(19) United States
(12) Patent Application Publication
(10) Pub. No.: US 2016/0013076 A1
(43) Pub. Date: Jan. 14, 2016

(54) THREE DIMENSIONAL PACKAGE ASSEMBLIES AND METHODS FOR THE PRODUCTION THEREOF

(71) Applicants: MICHAEL B. VINCENT, CHANDLER, AZ (US); ZHIWEI GONG, CHANDLER, AZ (US)

(72) Inventors: MICHAEL B. VINCENT, CHANDLER, AZ (US); ZHIWEI GONG, CHANDLER, AZ (US)

(21) Appl. No.: 14/330,971

(22) Filed: Jul. 14, 2014

(51) Int. Cl. H01L 21/56; H01L 25/10; H01L 21/78

(52) U.S. Cl. CPC H01L 21/561; H01L 21/78; H01L 25/105; H01L 2225/1064

(57) ABSTRACT

Three dimensional (3D) package assembly and methods for producing 3D package assembly are provided. In one embodiment, the method includes positioning a first plurality of microelectronic devices on a pre-singulated substrate package array. The microelectronic devices can be, for example, semiconductor; and the pre-singulated substrate package array can be a molded substrate panel. The first plurality of microelectronic devices is encapsulated while supported by the pre-singulated substrate package array to produce a direct-built panel containing the first plurality of microelectronic devices. The direct-built panel and the pre-singulated substrate package array are then singulated to yield a plurality of 3D package assemblies each comprised of a substrate package and a direct-built package. The direct-built package is bonded to the substrate package and containing at least one of the first plurality of microelectronic devices.

### TECHNICAL FIELD

Embodiments of the present invention relate generally to microelectronic packaging and, more particularly, to three dimensional package assemblies and methods for producing three dimensional packages assemblies wherein at least one package is fabricated directly on another package or interconnected array of packages.

### BACKGROUND

A so-called “three dimensional (3D) package assembly” can be produced by bonding and interconnecting multiple microelectronic packages in a stacked relationship. The stacked packages are commonly interconnected utilizing one or more Ball Grid Arrays (BGAs), Through Substrate Vias (TSVs), backside Redistribution Layers (RDLs), or the like. Such features can, however, add undesired complexity, cost, and height to the 3D package assembly. More recently, 3D package assemblies have been developed wherein electrically-conductive traces (referred to herein as “side connect traces”) are deposited on the package assembly sidewalls to interconnect the stacked packages. Advantageously, such side connect traces can be produced in a cost effective manner and without increasing the overall thickness of the 3D package assembly. However, the manufacturing processes utilized to produce 3D package assemblies including side connect traces remain limited in certain regards. For example, current manufacturing processes often utilize a pick-and-place tool to stack discrete packages on a package-by-package basis. Even when carefully controlled, such a discrete stacking approach may be incapable of ensuring precise rotational alignment between the stacked packages and, therefore, between the sidewall terminals contacted by the side connect traces. If sufficiently misaligned, the sidewall terminals may not be properly interconnected by the side connect traces when formed on the package sidewalls. Incomplete vertical interconnection of 3D package assemblies can thus occur thereby limiting manufacturing throughput and yield.

It is thus desirable to provide 3D package assemblies and methods for producing 3D package assemblies that enable precise rotational alignment between the stacked or overlying packages to be achieved on a reliable basis. Ideally, such methods would also enable multiple 3D package assemblies to be produced in parallel to improve manufacturing efficiency and throughput. Finally, it would also be desirable if, in at least in some embodiments, the 3D package assemblies could be produced to have reduced thicknesses and increased structural integrities as compared to other known 3D package assemblies. Other desirable features and characteristics of the present invention will become apparent from the subsequent Detailed Description and the appended Claims, taken in conjunction with the accompanying Drawings and the foregoing Background.

### BRIEF DESCRIPTION OF THE DRAWINGS

At least one example of the present invention will hereinafter be described in conjunction with the following figures, wherein like numerals denote like elements, and:

FIG. 1 is a cross-sectional view of a 3D package assembly including a substrate package and a direct-built package, which has been fabricated on the substrate package and which has a reduced thickness or height relative thereto, as illustrated in accordance with a first exemplary embodiment of the present invention;

FIGS. 2-7 are cross-sectional views of the 3D package assembly shown in FIG. 1, as illustrated at various stages of completion and fabricated in accordance with an exemplary embodiment of the present invention;

FIGS. 8-12 are cross-sectional views of a 3D package assembly including a direct-built package produced on a substrate package, as illustrated at various stages of completion and fabricated in accordance with a further exemplary embodiment of the present invention; and

FIGS. 13-16 are cross-sectional views of a 3D package assembly including a direct-built package produced over a substrate package, as illustrated at various stages of completion and fabricated in accordance with a still further exemplary embodiment of the present invention.

For simplicity and clarity of illustration, the drawing figures illustrate the general manner of construction, and descriptions and details of well-known features and techniques may be omitted to avoid unnecessarily obscuring the exemplary and non-limiting embodiments of the invention described in the subsequent Detailed Description. It should further be understood that features or elements appearing in the accompanying figures are not necessarily drawn to scale unless otherwise stated. For example, the dimensions of certain elements or regions in the figures may be exaggerated relative to other elements or regions to improve understanding of embodiments of the invention.

### DETAILED DESCRIPTION

The following describes exemplary embodiments of 3D package assemblies and methods for producing 3D package assemblies wherein at least a first microelectronic package is fabricated on or sequentially built over at least a second microelectronic package. The first package is referred to herein as a “direct-built package,” while the second package is referred to herein as a “substrate package.” In preferred implementations, a number of direct-built packages are produced on a corresponding number of substrate packages to allow a plurality of 3D package assemblies to be manufactured in parallel. In this case, the substrate packages can remain interconnected in a panel or wafer form during fabrication of the direct-built packages. Fabrication of the direct-built packages can entail encapsulation of a plurality of semiconductor die, while supported by the panel or wafer, to produce a direct-built panel. After additional processing, the direct-built panel and the underlying panel or wafer can be singulated to yield a plurality of 3D package assemblies each containing a direct-built package bonded to a substrate package. Side connect substrates are then formed on the sidewalls of the 3D package assemblies to interconnect the substrate and direct-built packages. Such a fabrication process can provide several benefits. For example, in at least some embodiments, the semiconductor die can be placed onto the interconnected substrate packages in a highly controlled manner to better ensure precise alignment between the sidewall terminals of the substrate packages and the corresponding sidewall terminals of the subsequently-produced direct-built packages. The packages can then be vertically interconnected by the formation of side connect traces in a highly reliable manner to maximizing throughput and yield during the manufacturing process. Additionally, in certain embodiments, the direct-built packages can be produced to have reduced thicknesses to minimize the overall thickness of the 3D package assembly and the length of the side connect traces.

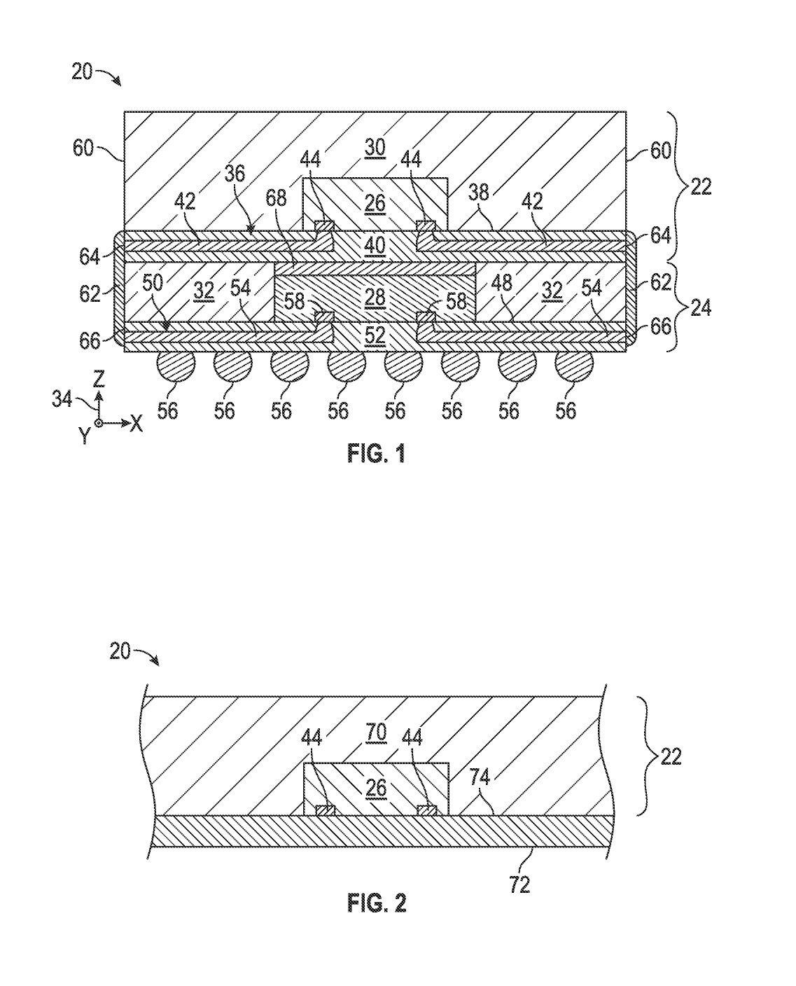

FIG. 1 is a cross-sectional of a 3D package assembly 20, as illustrated in accordance with an exemplary embodiment of the present invention. 3D package assembly 20 includes a substrate package 22 and a direct-built package 24, which are bonded in a layered or vertically-overlapping relationship. It will be appreciated that packages 22 and 24 are not physically “stacked” in the traditional sense as direct-built package 24 is fabricated directly on substrate package 22, as described more fully below in conjunction with FIGS. 2-7. Packages 22 and 24 each contain at least one microelectronic device or component. For example, as shown in FIG. 1, semiconductor die 26 and 28 can be contained within packages 22 and 24, respectively. Semiconductor die 26 and 28 overlap or vertically align, as taken along the package centerline or Z-axis (identified by in FIG. 1 by coordinate legend 34); however, this need not be the case in all embodiments. Packages 22 and 24 are produced utilizing a Fan-Out Wafer Level Packaging approach. Accordingly, packages 22 and 24 include molded bodies 30 and 32, respectively, in which semiconductor die 26 and 28 are embedded. In further embodiments, substrate package 22 can be produced utilizing a different type of packaging approach, such as a Fan-In Wafer Level Packaging (FI-WLP) approach.

A number of Redistribution Layers are formed over the respective frontsides of molded bodies 30 and 32. With respect to substrate package 22, specifically, RDLs 36 are produced over the frontside or build-up surface 38 of molded body 30 (corresponding to the lower principal surface of body 30 in the orientation shown in FIG. 1). RDLs 36 include a dielectric body 40 containing electrically-conductive interconnect lines 42, which are electrically coupled to bond pads 44 of die 26. Dielectric body 40 can be composed of a number of dielectric layers deposited over build-up surface 38, and interconnect lines 42 can be plated metal (e.g., copper) traces interspersed with the dielectric layers. As does molded body 30 of substrate package 22, molded body 32 of direct-built package 24 includes a frontside or build-up surface 48 over which one or more RDLs 50 are formed. Once again, RDLs 50 include a dielectric body 52 containing a plurality of electrically-conductive interconnect lines 54. BGA solder balls 56 are further produced over the frontside of RDLs 50 opposite molded body 32. Selected BGA solder balls 56 are electrically coupled to bond pads 58 of semiconductor die 28 via interconnect lines 54 to enable communication with packaged die 28 and with any other microelectronic devices contained within direct-built package 24. Interconnection between bond pads 44 of die 26 and BGA solder balls 56 can also be provided through a combination of interconnect lines 42 and 54, as well as side connect traces 62 (described below), to complete the wiring structure of 3D package assembly 20.

As shown in the accompanying figures and described herein, 3D package assembly 20 is provided by way of non-limiting example only. While a particular package architecture is shown in FIG. 1 for purposes of illustration, it will be appreciated that 3D package assembly 20 can be produced to include other types of internal wiring structures and Input/Output (I/O) interfaces including various different combinations of contact arrays (e.g., BGAs, externally-exposed solder pads, stud bumps, Land Grid Arrays, etc.), RDLs, leadframes, interposers, wire bonds, Through Package Vias, and so on. Moreover, 3D package assembly 20 need not include an externally-accessible contact array in all embodiments and can instead communicate wirelessly utilizing, for example, a Radio Frequency (RF) antenna structure. In this latter case, 3D package assembly 20 can be powered by an internal battery or by energy harvesting.

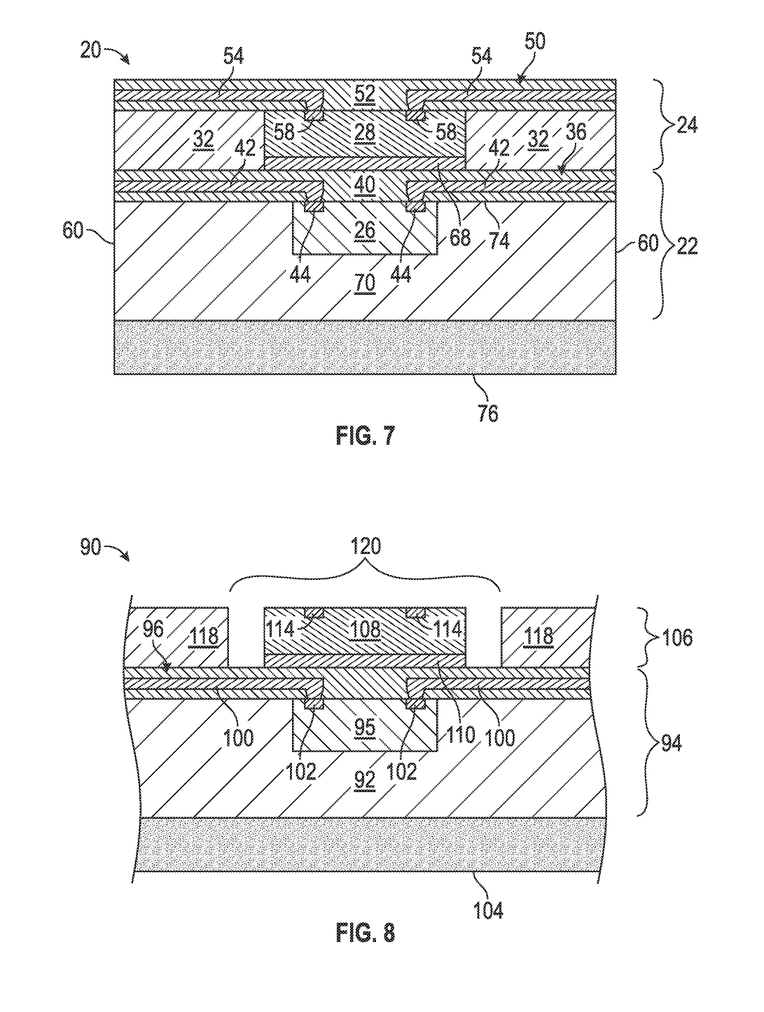

3D package assembly 20 includes package assembly sidewalls 60, which are defined by vertically aligning sidewalls of packages 22 and 24. One or more side connect traces 62 are formed on package assembly sidewalls 60. Side connect traces 62 vertically interconnect substrate package 22 and direct-built package 24 and, more specifically, semiconductor die 26 and 28. To enable such vertical interconnection, side connect traces 62 extend from points-of-contact provided on substrate package 22 to corresponding points-of-contact provided on direct-built package 24. In some embodiments, the points-of-contact can be provided on the backside of substrate package 22 and/or the frontside of direct-built package 24 (corresponding to the upper and lower principal surfaces of package assembly 20, respectively, in the orientation shown in FIG. 1). However, in many cases, the points-of-contact interconnected by side connect traces 62 will be located on the package assembly sidewalls 60 over which traces 62 extend. For example, as shown in FIG. 1, side connect traces 62 can electrically couple selected pairs of interconnect lines 42 and 54, which extend to package assembly sidewalls 60. The portions of interconnect lines 42 and 54 extending to package assembly sidewalls are referred to herein as “sidewall terminals,” as are any electrically-conductive features that extend to sidewalls 60 and are interconnected by traces 62. The sidewall terminals defined by interconnect lines 42 and 54 are identified in FIG. 1 by reference numerals “64” and “66,” respectively. The materials from which side connect traces 62 can be composed and methods for producing traces 62 are discussed further below in conjunction with FIG. 7.

As indicated above, direct-built package 24 is produced directly on substrate package 22 during manufacture of 3D package assembly 20. Prior to fabrication of package 24, semiconductor die 28 is bonded to substrate package 22 and, specifically, to the frontside surface of RDLs 36 utilizing a local adhesive layer 68. In contrast to a global adhesive layer of the type commonly utilized to bond separately-fabricated packages in a stacked relationship, local adhesive layer 68 is circumscribed or surrounded by molded body 32. Adhesive layer 68 can be, for example, a dispensed layer of die attach material, double-sided tap, or another material suitable for bonding die 28 to RDLs 36 and, more generally, to substrate package 22 during the below-described fabrication process. Such an approach of first bonding semiconductor die 28 to substrate package 22 and subsequently producing the remainder of package 24 around die 28 enables die 28 to be rotationally aligned to direct-built package 24 and die 26 in a highly precise manner. Sidewall terminals 66 of direct-built package 24 can consequently be produced to align precisely with sidewall terminals 64 of substrate package 22 to decrease the likelihood of incomplete or partially complete vertical interconnections during the subsequent formation of side connect traces 62. This increases the reliability with which 3D package assembly 20 can be produced on repeatable basis. As a further advantage, direct-built package 24 can be produced to have reduced thickness or height as compared to a substrate package 22. This allows the overall thickness of 3D package assembly 20 to be reduced, the lengths of side connect traces 62 to be minimized, and the overall structural integrity of traces 62 to be enhanced.

An exemplary embodiment of a manufacturing method suitable for producing 3D package assembly 20 along with a number of other package assemblies will now be described in conjunction with FIGS. 2-7. As shown in FIGS. 2-7 and described further below, the fabrication method is offered by way of non-limiting example only. It is emphasized that the fabrication steps shown in FIGS. 2-7 can be performed in alternative orders, that certain steps can be omitted in alternative embodiments, and that additional steps can be performed in alternative embodiments. Additionally, description of structure and processes known within the microelectronic package industry may be limited or entirely omitted without providing the well-known process details. In keeping with the exemplary embodiment shown in FIG. 1, substrate package 22 is described below as produced utilizing a Fan-Out Waver Level Packaging approach. It is emphasized, however, substrate package 22 can be produced utilizing other types of packaging approaches in further embodiments. For example, in alternative embodiments, substrate package 22 can be produced utilizing a FI-WLP approach during which the below-described process steps are performed on a wafer level; that is, utilizing non-singulated semiconductor wafer as opposed to a substrate panel containing a number of singulated semiconductor die. In either case, the substrate panel or wafer can be generically referred to as a “pre-singulated substrate package array,” which contains a number of interconnected substrate packages over which the direct-built packages are produced as described below.

With reference to FIG. 2, fabrication of 3D package assembly 20 can commence with production of substrate package 22. Substrate package 22 remains in panel form at the stage of manufacture shown in FIG. 2 and is consequently interconnected with a number of other partially-completed substrate packages (not shown) as a unitary or non-singulated substrate panel 70. As indicated above, substrate panel 70 can be generically referred to as a “pre-singulated substrate package array” and is more specifically referred to below as “substrate panel 70” to help distinguish panel 70 from the direct-built panel subsequently produced thereover. To avoid unnecessarily obscuring the drawing, a limited portion of substrate panel 70 is shown in FIG. 2 corresponding to substrate package 22. It will be appreciated, however, that substrate panel 70 will typically be considerably larger than the illustrated portion and contain other die incorporated into the other package assemblies produced in parallel with 3D package assembly 20. The other package assemblies produced in parallel with 3D package assembly 20 may or may not be substantially identical to 3D package assembly 20.

By way of non-limiting example, one process suitable for fabricating substrate panel 70 can be performed as follows. First, semiconductor die 26 and the other non-illustrated die are placed facedown on temporary substrate 72 (FIG. 2) using, for example, a pick-and-place tool. A non-illustrated mold frame having a central cavity or opening therein is then positioned over substrate 72 and around the semiconductor die. An electrically-insulative encapsulant or mold compound, such as a silica-filled epoxy, is then dispensed into the cavity of the mold frame and flows over the die. The encapsulant is solidified by thermal curing to yield substrate panel 70 in which die 26 and the other non-illustrated die are embedded. In further embodiments, substrate panel 70 can be produced utilizing various other known fabrication techniques including, for example, compression molding and lamination processes.

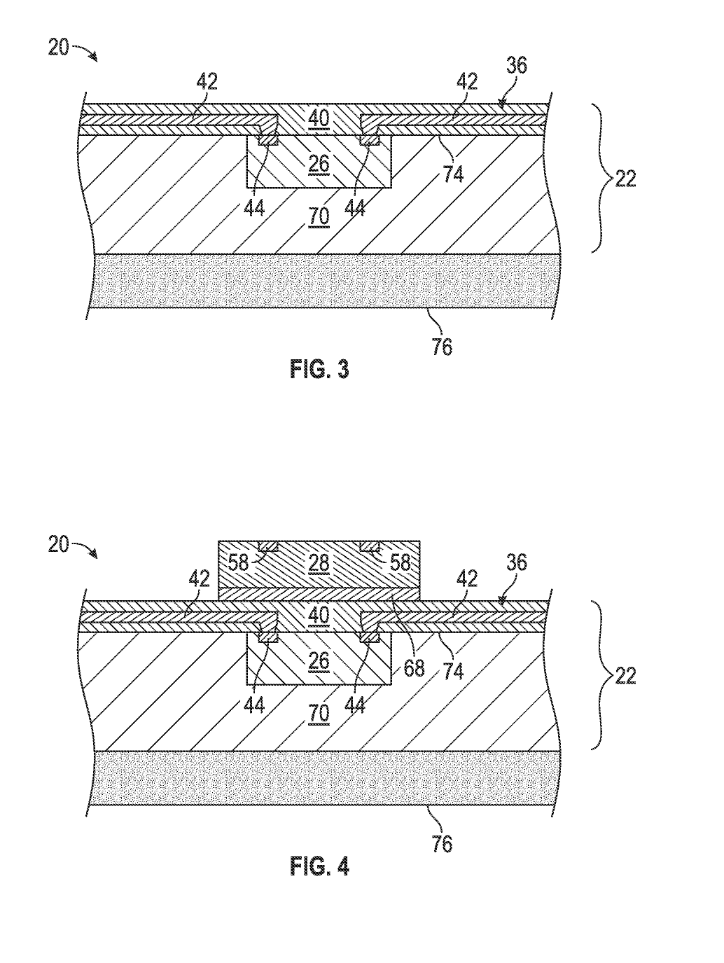

After encapsulation, substrate panel 70 can be thermally released or otherwise removed from temporary substrate 72 to reveal the frontside 74 of panel 70. Substrate panel 70 is then inverted and attached to a support structure, such as carrier 76 shown in FIG. 3. With frontside 74 of substrate panel 70 now facing upwards, RDLs 36 are sequentially built-up over substrate panel 70. During build-up of RDLs 36, dielectric body 40 can be produced by spinning-on or otherwise depositing one or more dielectric layers over panel frontside 74. Interconnect lines 42 can further be produced within dielectric body 40 utilizing well-known lithographical patterning and conductive material deposition techniques. In one embodiment, interconnect lines 42 are produced by patterning a mask layer deposited over a seed layer, plating exposed regions of the seed layer with copper or another metal, and then removing the mask layer to define interconnect lines 42.

After production of RDLs 36, semiconductor die 28 and a number of other semiconductor die are spatially distributed over substrate panel 70. In particular, the semiconductor die can be placed in a face-up orientation at selected locations on RDLs 36. As shown in FIG. 4, semiconductor die 28 can be positioned over semiconductor die 26 contained within substrate package 22 in a vertically overlapping or aligning relationship. As package 22 remains in panel form at the present stage of manufacture, the positioning and rotational alignment of die 28 with respect to substrate package 22 and, more generally, substrate panel 70 can be controlled with a high degree of precision. In this regard, fiducials or other optically-distinguishing features can be provided on substrate package 22 to allow optical alignment of die 28 utilizing, for example, a pick-and-place tool. In one embodiment, fiducials are provided on substrate panel 70 as metal features formed in RDLs 36 and located in the kerf regions of panel 70 or along the outer peripheral regions thereof. Furthermore, as semiconductor die 28 remains in a bare or unpackaged state at the present stage of manufacture, optically-distinguishable features present on the frontside of die 28, such as bond pads 58, can be utilized as visual reference points during the alignment process. The other non-illustrated semiconductor die are likewise positioned over their respective substrate packages included within substrate panel 70. The die can be placed individually or, instead, in groups utilizing a specialized fixture or end effector. To ensure that the die remain in their desired positions during the subsequently encapsulation process, semiconductor die 28 and the other non-illustrated die can be bonded directly to substrate panel 70 utilizing adhesive layers 68.

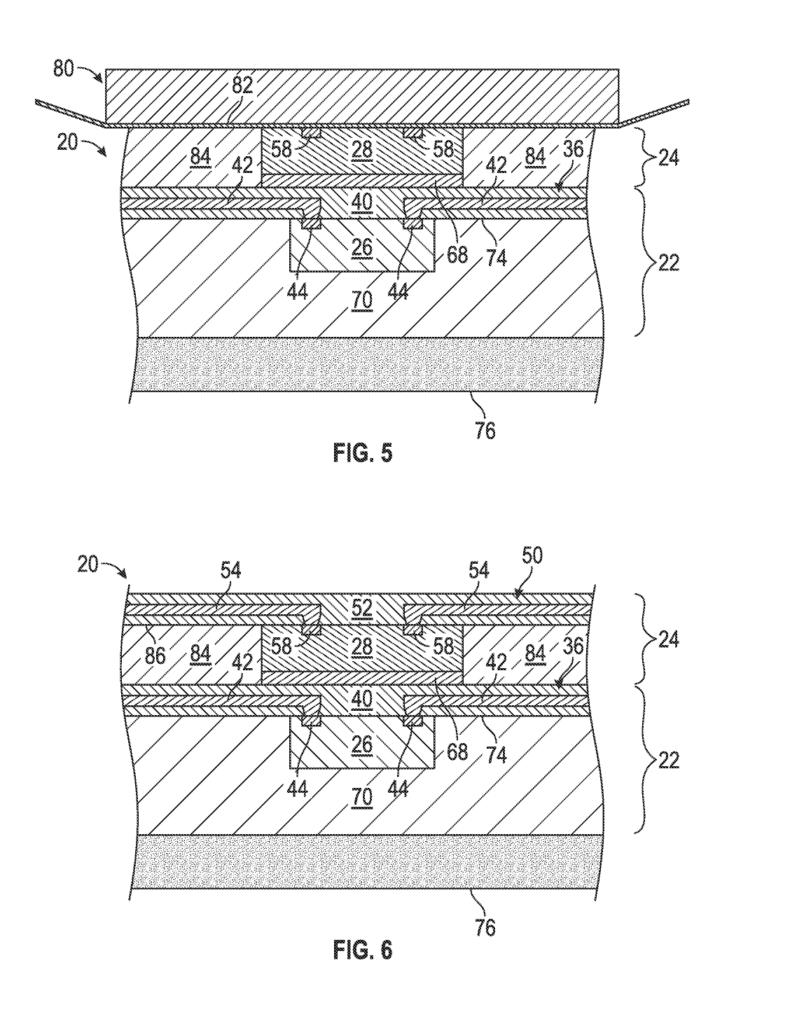

Semiconductor die 28 and the other non-illustrated die positioned on substrate panel 70 are next encapsulated. As die 28 is bonded to substrate panel 70 in a face-up orientation, bond pads 58 would be covered by the overmold material if die 28 were encapsulated utilizing a pour molding process of the type described above. In embodiments wherein the mold material is non-photoimagable, a Chemical Mechanical Polishing (CMP), grinding, lapping, or other material removal process can be carried-out to remove any mold overburden and again expose bond pads 58. Such a process can, however, potentially damage the circuitry located on the frontside of die 28 and is preferably avoided. Thus, a film assist molding process can instead be utilized to encapsulate die 28 and the surrounding die, while preventing the chosen mold material from covering the frontsides of die 28 and the other die positioned across panel 70. As generically illustrated in FIG. 5, film assist molding can be carried-out utilizing a film assist machine 80 including a sheet of adhesive film 82. The frontside of die 28 is adhered to and covered by adhesive film 82 during the molding process. In this manner, the mold material is prevented from flowing onto and covering the frontside of semiconductor die 28, while a direct-built panel 84 is produced around die 28 and bonded directly to RDLs 36 of substrate panel 70. Direct-built panel 84 is also formed around the other non-illustrated die, which are likewise adhered to adhesive film 82 along their respective frontsides. Substrate panel 70 and direct-built panel 84 are collectively referred to hereafter as “dual panel structure 70, 84.”

Advancing to FIG. 6, dual panel structure 70, 84 is removed from the film assist machine 80 (FIG. 5) to reveal the frontside 86 of direct-built panel 84. Afterwards, RDLs 50 are produced over panel frontside 86 utilizing, for example, a build-up process similar to that described above in conjunction with the production of RDLs 36. During production of RDLs 50, a number of dielectric layers can be sequentially deposited to form dielectric body 52, while a plating process is utilized to form interconnect lines 54. Notably, rotational offset between interconnect lines 54 and interconnect lines 42 can be reduced or eliminated due to the precise rotational alignment between the die contained within direct-built panel 84 and the die contained within substrate panel 70. With respect to partially-fabricated package assembly 20, specifically, the precise rotational alignment between die 26 and 28 enables any offset between the newly-formed interconnect lines 42 and interconnect lines 54 to be minimized. After build-up of RDLs 50, the dual panel structure 70, 84 formed by substrate panel 70 and direct-built panel 84 is singulated. Singulation can be carried-out utilizing a dicing saw; however, other singulation processes can also be employed including, for example, laser cutting or water jetting.

FIG. 7 illustrates 3D package assembly 20 after singulation of substrate panel 70 and direct-built panel 84. The singulated piece of substrate panel 70 included within 3D package assembly 20 defines molded body 32 of substrate package 22, while the singulated piece of direct-built panel 84 included within package assembly 20 defines molded body 30 of direct-built package 24. Singulation of the dual panel structure 70, 84 also defines package assembly sidewalls 60, sidewall terminals 64, and sidewall terminals 66. As interconnect lines 54 have been produced in relatively precise rotational alignment with interconnect lines 42, precise alignment is also maintained between sidewall terminals 64 and 66. As a result, interconnect lines 42 and 54 can be reliably interconnected via the formation of side connect traces 62, which can be printed or otherwise produced on the package sidewalls in the below-described manner. The various other 3D package assembly produced by singulation of the dual panel structure 70, 84 likewise include sidewall terminals exposed through the package sidewalls, which can be interconnected by the formation of sidewall connect traces as described below. Finally, although not shown in FIG. 7 for clarity, BGA solder balls 56 can also be produced over the outer solder mask layer of RDLs 50 prior to singulation of dual panel structure 70, 84.

Side connect traces 62 are next formed on package assembly sidewalls 60 to interconnect packages 22 and 24 and thereby complete the production of 3D package assembly 20 (as shown in FIG. 1). Side connect traces 30 can be produced utilizing any one of a number of different processes. In one embodiment, a printing technique is utilized wherein an electrically-conductive ink is dispensed or deposited over the package sidewalls in a predetermined pattern or design. A non-exhaustive list of suitable printing techniques includes inkjet printing, aerosol printing, screen printing, and needle dispensing techniques. Suitable electrically-conductive inks include, but are not limited to, inks containing relatively small metal particles, such as gold or silver particles in the nanometer range (e.g., particles having average diameters ranging from about 2 to about 50 nanometers). Thermal or ultraviolet curing can be performed after printing of the electrically-conductive ink traces, as appropriate. In further embodiments, an electrically-conductive layer, such as an electrically-conductive paste or metal layer, can be deposited over package assembly sidewalls 60 and then patterned by lithographical patterning, laser ablation, or another patterning process. The thickness of side connect traces 62 can be between about 5 and about 10 microns in an embodiment. In other embodiments, side connect traces 62 can be thicker or thinner than the aforementioned range.

There has thus been provided a process for fabricating 3D package assemblies wherein one or more direct-built packages are produced over one or more substrate packages. The above-described fabrication process enables precise alignment between sidewall terminals included within overlying packages and interconnected by the side connect traces. Manufacturing throughput and yield are improved as a result. Additionally, the above-described fabrication process enables the production of low profile direct-built packages to minimize the overall height of the 3D package assembly, decrease the length of the side connect traces, and enhance the overall structural integrity of the 3D package assembly. In the above-described exemplary embodiment, a film assist molding process is utilized to produce a molded substrate panel directly over an underlying substrate structure containing an array of interconnected packages. As described above, film assist molding enables semiconductor die to be encapsulated within a molded compound, while preventing the undesired overflow of the non-photoimagable mold compound onto the respective frontsides of the encapsulated die. However, in further embodiments, the chosen encapsulant can be permitted to flow over the encapsulated die and openings or vias can subsequently be formed in the encapsulant to reveal the die frontsides and, specifically, the bond pads located thereon. In such implementations, a photo-imageable material can be selected as the encapsulant or overmold material and lithographical patterning can be utilized to reveal the die bond pads after encapsulation. An example of such a fabrication process will now be described in conjunction with FIGS. 8-11.

FIGS. 8-12 illustrate an exemplary 3D package assembly 90, as illustrated at various stages of completion and produced in accordance with a further exemplary embodiment of the present invention. As was the case previously, 3D package assembly 90 is produced utilizing a molded substrate panel 92 containing an interconnected array of substrate packages 94. Substrate panel 92 can be produced in essentially the same manner as substrate panel 70, as described above in conjunction with FIGS. 2-7. A plurality of semiconductor die 95 is embedded in substrate panel 92, with at least one die 95 included in the region of panel 92 corresponding to the illustrated substrate package 92. One or more RDLs 96 are further produced over the frontside or build-up surface of substrate panel 92. RDLs 96 include a dielectric body containing a plurality of interconnect lines 100, which are electrically coupled to bond pads 102 of die 95. As further shown in FIG. 8, a support structure or carrier 104 is utilized to support substrate panel 70 during build-up of RDLs 96 and the subsequent formation of a direct-built panel, as described more fully below.

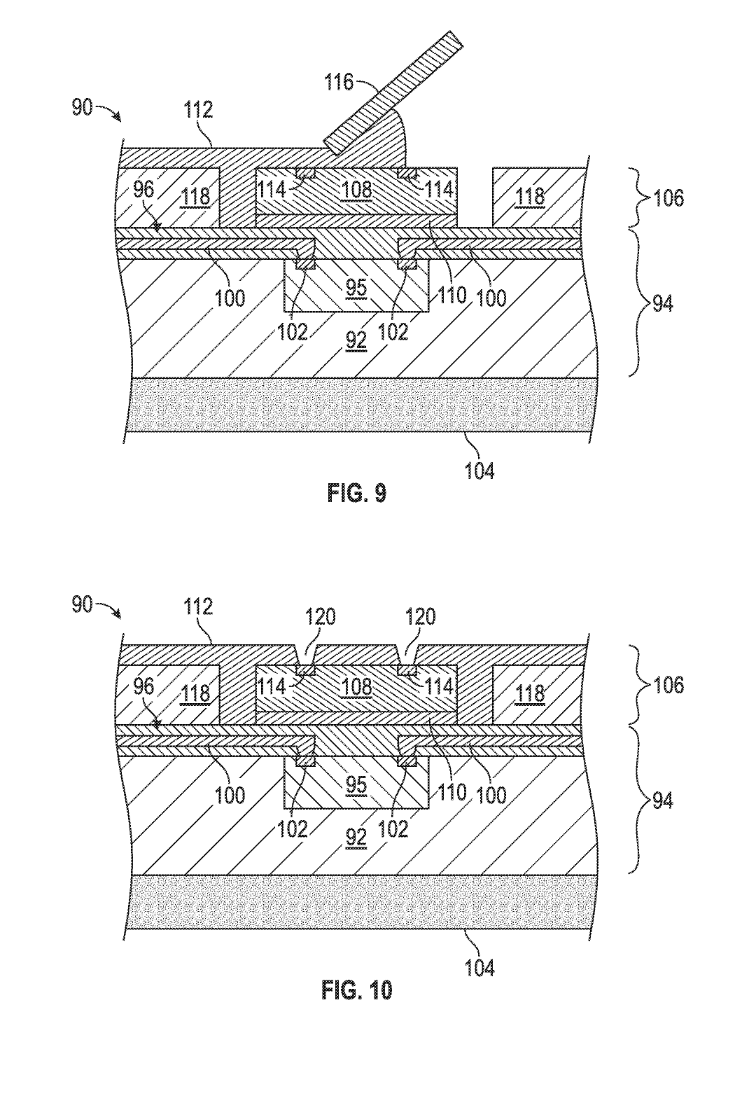

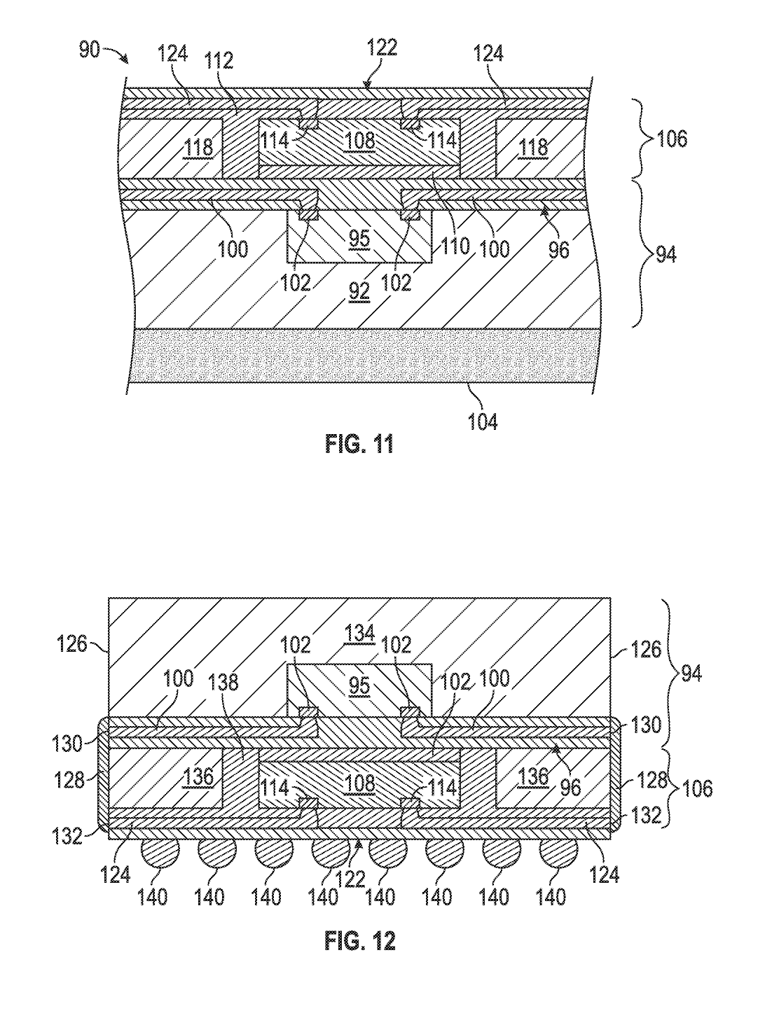

A molded panel containing a number of direct-built packages 106 is next produced over substrate panel 92. FIG. 8 depicts one such direct-built package 106, which is contained within 3D package assembly 90 and which is shown in a partially-completed state. To produce direct-built packages 106, a plurality of semiconductor die 108 is first positioned in a face-up orientation and at selected locations across the upper surface of RDLs 96. Semiconductor die 108 can be placed in their desired positions utilizing a pick-and-place tool and can be bonded to the outermost solder mask layer of RDLs 96 utilizing adhesive layers 110. After positioning and bonding of die 108, a photo-imageable encapsulant layer 112 is next dispensed over substrate panel 92 and die 108 (shown in FIG. 9). Encapsulant layer 112 is applied over the frontsides of die 108 and covers bond pads 114 located thereon. As indicated in FIG. 9, a screen printing technique can be carried-out during which a specialized squeegee 116 is utilized to apply encapsulant material 112 over and around die 108. Encapsulant material 112 can be solder mask dielectric material or another flowable, photo-imageable dielectric material. If desired, a pre-mold frame 118 can be positioned over substrate panel 92 and around die 108 prior to dispensing of encapsulant layer 112. Pre-mold frame 118 enhances the mechanical strength of the molded panel body produced by encapsulant layer 112 and helps to ensure that a relatively planar upper surface is created to facilitate built-up of RDLs 122 (shown in FIGS. 11 and 12). Pre-mold frame 118 can be composed of a generally rigid, dielectric material, such as ceramic or resin. Pre-mold frame 118 is produced to include a plurality of openings 120 (one of which is identified in FIG. 9), which accommodate die 108 when frame 118 is positioned over panel 92. Circumferential clearances are provided around die 108 and the interior sidewalls of frame 118 defining openings 120. When encapsulant layer 112 is applied over die 108 and frame 118, the clearances are filled with the encapsulant material. When cured, encapsulant layer 112 combines with pre-mold frame 118 to produce a direct-built panel 112, 118, as identified in FIG. 10.

To complete fabrication of 3D package assembly 90 and the other package assemblies, lithographic patterning is carried-out to create openings 120 in encapsulant layer 112 exposing bond pads 114. As shown in FIG. 11, RDLs 122 are then produced containing interconnect lines 124 in contact with bond pads 114. Substrate panel 92 and direct-built panel 112, 118 are subsequently singulated and side connect traces are formed over the package assembly sidewalls to yield a number of completed 3D package assemblies including package assembly 90. As can be seen in FIG. 12, singulation of substrate panel 92 and direct-built panel 112, 118 imparts package assembly 90 with substantially vertical sidewalls 126. Electrically-conductive side connect traces 122 are then printed or otherwise produced on sidewalls 126 to interconnect substrate package 94 and direct-built package 106. In particular, side connect traces 122 extend between the laterally-exposed regions of interconnect lines 100 and 124 (identified in FIG. 12 as sidewall terminals “130” and “132,” respectively) to electrically interconnect die 95 contained in package 94 and die 108 contained in the illustrated package 106. The singulated piece of substrate panel 92 included within 3D package assembly 90 defines the molded body of substrate package 94 and is identified by reference numeral “134.” Similarly, the singulated piece of direct-built panel 112, 118 defines the body of direct-built package 106 and is identified as “136, 138.” If desired, a BGA including solder balls 140 can be produced over the outermost solder mask layer of RDLs 122 to enable electrical communication with die 95, die 108, and any other microelectronic devices contained within 3D package assembly 90.

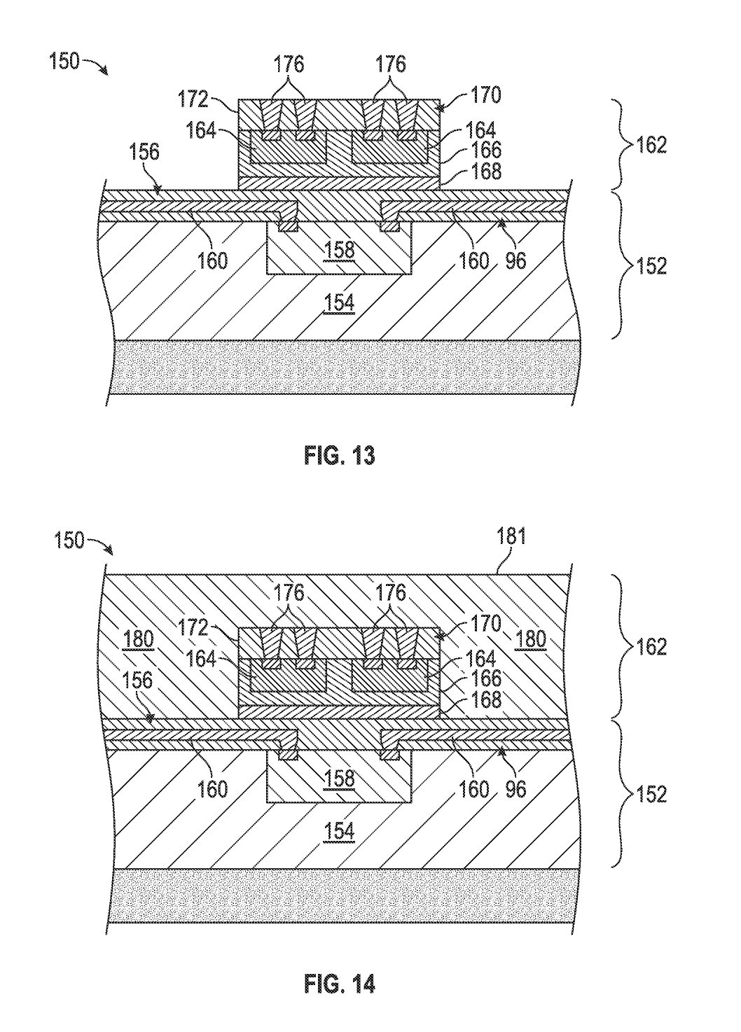

There has thus been described an further exemplary method for producing a 3D package assemblies wherein one or more direct-built packages are produced over one or more substrate packages. As in the fabrication method described above in conjunction with FIGS. 1-7, the fabrication described in conjunction with FIGS. 8-12 avoids the usage of a planarization (e.g., a CMP, grinding, or lapping) process to reveal the frontside of the die encapsulated within the direct-built panel. However, such a planarization process can be utilized in still further embodiments of the fabrication method. In this case, a protective, interconnect buffer layer can first be produced over the frontsides of the die embedded within the direct-built panel. The interconnect layer is considered a “buffer layer” in that this layer serves to protect the die from damage during planarization of the direct-built panel. An example of such a fabrication process will now be described in conjunction with FIGS. 13-16.

FIGS. 13-16 illustrate a 3D package assembly 150, as shown at various stages of completion and produced in accordance with a still further exemplary embodiment of the present invention. With initial reference to FIG. 13, 3D package assembly 150 can be produced utilizing a pre-singulated substrate package array containing multiple interconnect substrate packages 152 (one of which is shown in FIG. 13). As was the case previously, pre-singulated substrate package array assumes the form of a substrate panel 154 (partially shown) over which one or more RDLs 156 are produced. A plurality of semiconductor die 158 is embedded in panel 154 and electrically coupled to interconnect lines 160 contained within RDLs 156. A number of direct-built packages 162 (one of which is shown in FIG. 13) is further produced over substrate panel 154. To produce direct-built packages 162, an array of semiconductor die 164 is first distributed across the frontside of substrate panel 154. In the illustrated embodiment, a two semiconductor die 164 are included within the direct-built package 162 fabricated over the illustrated substrate package 152. Semiconductor die 164 have been pre-encapsulated in an inner molded body 166, which is bonded to RDLs 156 via adhesive layer 168. An interconnect buffer layer 170 is formed over inner molded body 166. Semiconductor die 158, inner molded body 166, and interconnect buffer layer 170 are also collectively referred to herein as “package core 158, 166, 170.”

Interconnect buffer layer 170 serves to protect die 164 from damage during the below-described planarization process, while also providing electrical connection to the die bond. Interconnect buffer layer 170 can assume any form suitable for performing these functions. As indicated in FIG. 13, interconnect buffer layer 170 can include a dielectric layer or film 172 deposited or otherwise formed over the frontsides of die 164 and inner molded body 166, as well as a number of electrically-conductive raised contacts 176 extending through film 172 to ohmically contact the bond pads of die 164. Raised contacts 176 can assume the form of any electrically-conductive structure or body suitable for providing electrical contact to the die bond pads including, but not limited to, plated metal pillars or stud bumps. In further embodiments, interconnect buffer layer 170 may not include dielectric film 172 and the voids between raised contacts 176 may be filled by the mold compound during encapsulation of package core 158, 166, 170, as described below.

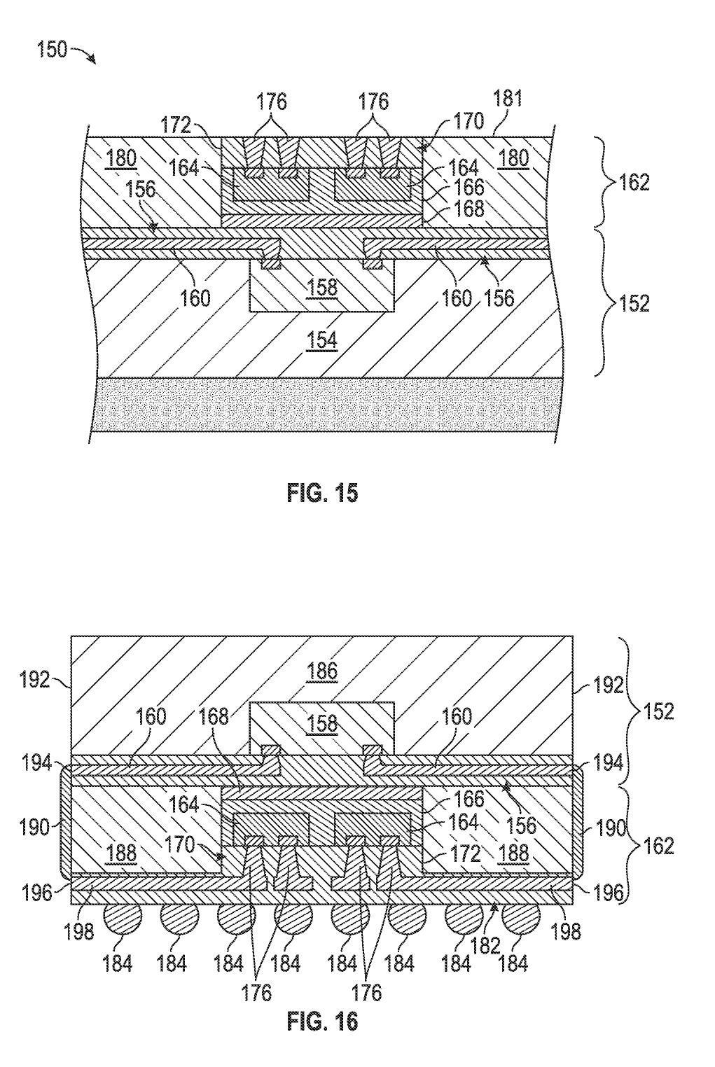

An encapsulation or overmolding process is performed during which package cores 158, 166, 170 are embedded within a molded panel. The encapsulation process can be carried-out in essentially the same manner as previously described; that is, a mold compound may be dispensed over package cores 158, 166, 170 while cores 158, 166, 170 are supported by substrate panel 154. The resultant structure is shown in FIG. 14 wherein the direct-built panel is identified by reference numeral “180” and only partially shown. As can be seen, package cores 158, 166, 170 and, specifically, interconnect buffer layers 170 are covered by frontside 181 of direct-built panel 180. Planarization is carried-out to remove material from panel frontside 181 and thereby expose interconnect buffer layers 170 therethrough. Planarization can be carried-out utilizing any process suitable for removing a predetermined thickness from direct-built panel 180, while imparting panel frontside 181 with a substantially planar surface. In preferred embodiments, a CMP, lapping, or grinding process is utilized. FIG. 15 illustrates direct-built panel 180 after the performance of such a planarization process and exposure of interconnect buffer layers 170 through newly-planarized frontside 181 of direct-built panel 180. Upper portions of interconnect buffer layers 170 will also typically be removed during the planarization process.

Additional processing of substrate panel direct-built panel 180 is now performed to complete fabrication of 3D package assembly 150 (illustrated in a complete state in FIG. 16). With reference to FIG. 16, a number of RDLs 182 are formed over panel 180, BGA solder balls 184 are formed over the outermost solder mask layer of RDLs 182, and then panel singulation is carried-out. Panel singulation imparts substrate package 152 and direct-built package 162 with molded bodies 186 and 188, respectively, as cleaved from panels 154 and 180 (identified in FIGS. 14 and 15). Side connect traces 190 are printed or otherwise formed over selected regions of package assembly sidewalls 192 to interconnect the sidewall terminals 194 and 196 provided on substrate package 152 and direct-built package 162. As was the case previously, sidewall terminals 194 are defined by the regions of interconnect lines 160, which extend to and are exposed at package assembly sidewalls 192. Similarly, sidewall terminals 196 are defined by laterally-exposed regions of interconnect lines 198 included within RDLs 182. Side connect traces 190 thus electrically couple die 158 and 164 through interconnect lines 160 and 198 to vertically interconnect package 152 and 162.

There has thus been provided a process for fabricating 3D package assemblies wherein one or more direct-built packages are produced over one or more substrate packages. The above-described fabrication processes ensure precise rotational alignment between the overlying packages or package layers and, therefore, accurate alignment between the sidewall terminals or pads of the packages. This, in turn, helps to ensure that vertical interconnection of the 3D package assemblies can be fully and repeatedly achieved by printing or otherwise forming side connect traces on the package sidewalls. Manufacturing throughput and yield are improved as a result. Additionally, the above-described fabrication process enabled the production of low profile direct-built packages to minimize the overall height of the 3D package assembly, decrease the length of the side connect traces, and enhance overall structural robustness of the package assembly.

In one embodiment, the above-described fabrication process includes positioning a first plurality of microelectronic devices on a pre-singulated substrate package array. The microelectronic devices can be, for example, semiconductor; and the pre-singulated substrate package array can be a molded substrate panel. The first plurality of microelectronic devices is encapsulated while supported by the pre-singulated substrate package array to produce a direct-built panel containing the first plurality of microelectronic devices. The direct-built panel and the pre-singulated substrate package array are then singulated to yield a plurality of 3D package assemblies each comprised of a substrate package and a direct-built package. The direct-built package is bonded to the substrate package and containing at least one of the first plurality of microelectronic devices.

In another embodiment, the above-described fabrication process positioning a first microelectronic device on a substrate package containing a second microelectronic device. A direct-built package, such as a FO-WLP, is fabricated around the first microelectronic device and over the substrate package. At least one side connect trace is printed or otherwise formed to extend from a sidewall of the substrate package to an aligning sidewall of the direct-built package to interconnect the first and second microelectronic devices. In certain embodiments, the first microelectronic device can be bonded to the substrate package, is interconnected with a plurality of other substrate packages as a substrate panel. In this case, the first microelectronic device can be a semiconductor die, which is rotationally aligned to the substrate panel during the step of positioning. In a further embodiment, the direct-built package is fabricated by encapsulating the first microelectronic device along with a plurality of other microelectronic device to produce a direct-built panel bonded to the substrate panel, by producing one or more RDLs over the direct-built panel, and by singulating the direct-built panel and the substrate panel to yield a plurality of 3D package assemblies.

The foregoing has also provided embodiments of a 3D package assembly. In one embodiment, the 3D package assemblies includes a substrate package, a direct-built package fabricated over the substrate package, a first microelectronic device contained within the direct-built package, and a second microelectronic device contained within substrate package. One or more side connect traces extending from a sidewall of the substrate package to an aligning sidewall of the direct-built package to electrically interconnect the first and second microelectronic devices. The direct-built package can be a FO-WLP. In an embodiment, the 3D package assembly further includes an adhesive layer bonding the first microelectronic device to the substrate package. In a further embodiment, the substrate package includes one or more RDLs, and the first microelectronic device is a semiconductor die having a backside bonded to the RDLs. In a still further embodiment, the first microelectronic device is a semiconductor die, and the direct-built package includes a molded body having a thickness substantially equivalent to the height of the semiconductor die. Finally, in certain cases, the first and second microelectronic devices an overlap, as taken along a vertical axis extending through the 3D package assembly.

While at least one exemplary embodiment has been presented in the foregoing Detailed Description, it should be appreciated that a vast number of variations exist. It should also be appreciated that the exemplary embodiment or exemplary embodiments are only examples, and are not intended to limit the scope, applicability, or configuration of the invention in any way. Rather, the foregoing Detailed Description will provide those skilled in the art with a convenient road map for implementing an exemplary embodiment of the invention. It being understood that various changes can be made in the function and arrangement of elements described in an exemplary embodiment without departing from the scope of the invention as set-forth in the appended claims.

As appearing in the foregoing Detailed Description, terms such as “comprise,” “include,” “have,” and the like are intended to cover non-exclusive inclusions, such that a process, method, article, or apparatus that comprises a list of elements is not necessarily limited to those elements, but can include other elements not expressly listed or inherent to such process, method, article, or apparatus. As still further appearing herein, terms such as “over,” “under,” “on,” and the like are utilized to indicate relative position between two structural elements or layers and not necessarily to denote physical contact between structural elements or layers. Thus, a first structure or layer can be described as fabricated “over” or “on” a second structure, layer, or substrate without indicating that the first structure or layer necessarily contacts the second structure, layer, or substrate due to, for example, presence of one or more intervening layers. As appearing further herein, the term “microelectronic device” is utilized in a broad sense to refer to an electronic device, element, or structure produced on a relatively small scale and amenable to packaging in the above-described manner. Microelectronic devices include, but are not limited to, integrated circuits formed on semiconductor die, Microelectromechanical Systems (MEMS) devices, passive electronic components, optical devices, and other small scale electronic devices capable of providing processing, memory, sensing, radiofrequency, optical, and actuator functionalities, to list but a few examples. Microelectronic devices also include other discrete or separately-fabricated structures that can be integrated into the package, such as prefabricated via structures and prefabricated antenna structures.

What is claimed is:

1. A method for fabricating three dimensional (3D) package assemblies, the method comprising:
positioning a first plurality of microelectronic devices on a pre-singulated substrate package array;
encapsulating the first plurality of microelectronic devices while supported by the pre-singulated substrate package array to produce a direct-built panel containing the first plurality of microelectronic devices; and
singulating the direct-built panel and the pre-singulated substrate package array to yield a plurality of 3D package assemblies each comprised of a substrate package and a direct-built package, the direct-built package bonded to the substrate package and containing at least one of the first plurality of microelectronic devices.

2. The method of claim 1 wherein the first plurality of microelectronic devices comprise semiconductor die, and wherein positioning comprises bonding the semiconductor die in a face-up orientation to the pre-singulated substrate package array.

3. The method of claim 2 wherein the pre-singulated substrate package array comprises a molded panel over which one or more Redistribution Layers (RDLs) are formed, and wherein bonding comprises bonding the semiconductor die to the RDLs.

4. The method of claim 1 wherein the first plurality of microelectronic devices comprise semiconductor die having frontsides, and wherein encapsulating comprises utilizing a film assist molding process to encapsulate the semiconductor die, while preventing the flow of mold material onto the frontsides of the semiconductor die.

5. The method of claim 1 wherein the first plurality of microelectronic devices comprise semiconductor die over which interconnect buffer layers are formed, and wherein encapsulating comprises:
overmolding the semiconductor die such that mold material covers the interconnect buffer layers; and
removing portions of the mold material overlying the interconnect buffer layers to expose the interconnect buffer layers through a frontside surface of the direct-built panel.

6. The method of claim 5 further comprising producing one or more Redistribution Layers (RDLs) over the frontside surface of the direct-built panel, the RDLs containing interconnect lines electrically coupled to the semiconductor die through the interconnect buffer layers.

7. The method of claim 1 wherein the first plurality of microelectronic devices comprise semiconductor die having bond pads, and wherein encapsulating comprises:
dispensing a photoimagable dielectric material around the semiconductor die and over the bond pads; and
photo-imaging the photoimagable dielectric material to create openings therein exposing the bond pads.

8. The method of claim 7 further comprising positioning a pre-mold frame on the pre-singulated substrate package array prior to dispensing the photoimagable dielectric material, the pre-mold frame having openings in which the semiconductor die are received.

9. The method of claim 1 wherein the pre-singulated substrate package array contains a second plurality of microelectronic devices, and wherein positioning comprises placing each of the first plurality of microelectronic devices at a location vertically overlying at least one of the second plurality of microelectronic devices.

10. The method of claim 1 further comprising, for one or more of the plurality of 3D package assemblies, forming side connect traces on at least one sidewall of the 3D package assembly vertically interconnecting the substrate package and the direct-built package.

11. A method for producing three dimensional (3D) package assemblies, the method comprising:
positioning a first microelectronic device on a substrate package containing a second microelectronic device;
fabricating a direct-built Fan-Out Wafer Level Package (FO-WLP) around the first microelectronic device and over the substrate package; and
forming at least one side connect trace extending from a sidewall of the substrate package to an aligning sidewall of the direct-built FO-WLP to interconnect the first and second microelectronic devices.

12. The method of claim 11 wherein positioning comprises bonding the first microelectronic device to the substrate package, while the substrate package is interconnected with a plurality of other substrate packages as a substrate panel.

13. The method of claim 12 wherein the first microelectronic device comprises a semiconductor die, and wherein positioning comprises rotationally aligning the semiconductor die to the substrate panel.

14. The method of claim 12 wherein fabricating comprises:
encapsulating the first microelectronic device along with a plurality of other microelectronic device to produce a direct-built panel bonded to the substrate panel;
producing one or more Redistribution Layers (RDLs) over the direct-built panel; and
singulating the direct-built panel and the substrate panel to yield a plurality of 3D package assemblies.

15. A three dimensional (3D) package assembly, comprising:
a substrate package;
a direct-built package fabricated over the substrate package;
a first microelectronic device contained within the direct-built package;
a second microelectronic device contained within substrate package; and
one or more side connect traces extending from a sidewall of the substrate package to an aligning sidewall of the direct-built package to electrically interconnect the first and second microelectronic devices.

16. The 3D package assembly of claim 15 wherein the direct-built package comprises a Fan-Out Wafer Level Package.

17. The 3D package assembly of claim 15 further comprising an adhesive layer bonding the first microelectronic device to the substrate package.

18. The 3D package assembly of claim 17 wherein the substrate package comprises one or more Redistribution Layers (RDLs), and wherein the first microelectronic device comprises a semiconductor die having a backside bonded to the RDLs.

19. The 3D package assembly of claim 15 wherein the first microelectronic device comprises a semiconductor die, and wherein the direct-built package comprises a molded body having a thickness substantially equivalent to the height of the semiconductor die.

20. The 3D package assembly of claim 15 wherein the first and second microelectronic devices overlap, as taken along a vertical axis extending through the 3D package assembly.
